(19) United States
(12) Patent Application Publication
(10) Pub. No.: US 2018/0350642 A1
(43) Pub. Date: Dec. 6, 2018

(54) Method of Manufacturing Semiconductor Device

(71) Applicant: Hitachi Kokusai Electric Inc., Tokyo (JP)

(72) Inventor: Yasuhiro MIZUGUCHI, Toyama (JP)

(21) Appl. No.: 15/699,321

(22) Filed: Sep. 8, 2017

(30) Foreign Application Priority Data
May 31, 2017 (JP) 2017-108136

(51) Int. Cl. H01L 21/67; H01J 37/32; G06F 11/34; G06F 11/30

(52) U.S. Cl. CPC H01L 21/67253; G06F 11/3013; G06F 11/3409; H01J 37/32522

(57) ABSTRACT

A technique capable of facilitating a determination of a state of a process chamber is provided. According to the technique described herein, there is provided a method of manufacturing a semiconductor device, including: (a) acquiring a first process chamber data representing a state of a process chamber without a substrate loaded in the process chamber while controlling a heating unit provided in the process chamber and an atmosphere controller configured to control an atmosphere of the process chamber; (b) acquiring a second process chamber data representing the state of the process chamber with the substrate loaded in the process chamber while controlling the heating unit and the atmosphere controller to process the substrate; and (c) displaying the first process chamber data and the second process chamber data along with a first reference data and a second reference data acquired in advance on a display screen while performing (b).

### CROSS REFERENCE TO RELATED APPLICATIONS

This application claims foreign priority under 35 U.S.C. § 119(a)-(d) to Application No. JP 2017-108136 filed on May 31, 2017, the entire contents of which are hereby incorporated by reference.

### TECHNICAL FIELD

The present disclosure relates to a method of manufacturing a semiconductor device.

### BACKGROUND

A substrate processing apparatus may be in operation or not in operation. When a wafer to be processed is not present in the substrate processing apparatus, e.g., when the substrate processing apparatus is under maintenance between lots or before the wafer is loaded into the substrate processing apparatus, a process chamber of the substrate processing apparatus is not in operation. During or after the loading of the wafer, the substrate processing apparatus is put into operation, and a predetermined substrate processing is then performed.

When the substrate processing apparatus is not in operation, the state of the substrate processing apparatus does not satisfy the processing conditions required to process the substrate. For example, the temperature of the process chamber that is not in operation may be lower than that of the process chamber when the substrate is processed. That is, the state of the substrate processing apparatus immediately after the substrate processing apparatus is put into operation, i.e. when the substrate (wafer) is processed for the first time may be different from the state of the substrate processing apparatus after the plurality of substrates are processed. This difference causes a deviation in the quality of substrate processing. Therefore, before the substrate is processed, the state of the process chamber should be adjusted such that the state of the process chamber is close to or substantially the same as the processing condition. For example, before loading the first substrate of a lot into the substrate processing apparatus, a heater should be put into operation such that the temperature of the process chamber is close to the temperature specified in the processing condition. As a result, the state of the substrate processing apparatus for the first substrate may be identical to the processing condition, and deviations in the quality of the substrate processing may be suppressed.

Particularly, in order to suppress the deviation, it is required to accurately determine the state of the process chamber.

### SUMMARY

Described herein is a technique capable of facilitating the determination of the state of the process chamber.

According to one aspect of the technique described herein, there is provided a method of manufacturing a semiconductor device, including: (a) acquiring a first process chamber data representing a state of a process chamber without a substrate loaded in the process chamber while controlling a heating unit provided in the process chamber and an atmosphere controller configured to control an atmosphere of the process chamber; (b) acquiring a second process chamber data representing the state of the process chamber with the substrate loaded in the process chamber while controlling the heating unit and the atmosphere controller to process the substrate; and (c) displaying the first process chamber data and the second process chamber data along with a first reference data and a second reference data acquired in advance on a display screen while performing (b).

### BRIEF DESCRIPTION OF THE DRAWINGS

FIG. 1 is a diagram illustrating a flow of processes performed by a substrate processing apparatus according to an embodiment.

FIG. 2 schematically illustrates the substrate processing apparatus according to the embodiment.

FIG. 3 is a cross-sectional view schematically illustrating the substrate processing apparatus according to the embodiment.

FIG. 4 schematically illustrates a pod of the substrate processing apparatus according to the embodiment.

FIG. 5 is a cross-sectional view schematically illustrating a reactor of the substrate processing apparatus according to the embodiment.

FIG. 6 is a block diagram illustrating a controller of the substrate processing apparatus and peripherals thereof according to the embodiment.

FIG. 7 schematically illustrates an example of a table of monitored steps and acquired data according to the embodiment.

FIG. 8 schematically illustrates another example of a table of monitored steps and acquired data according to the embodiment.

FIG. 9 is an exemplary graph depicting acquired data representing a state of the reactor according to the embodiment.

FIG. 10 is another exemplary graph depicting acquired data representing a state of the reactor according to the embodiment.

FIG. 11 is an exemplary graph depicting acquired data representing a state of the reactor according to a comparative example.

### DETAILED DESCRIPTION

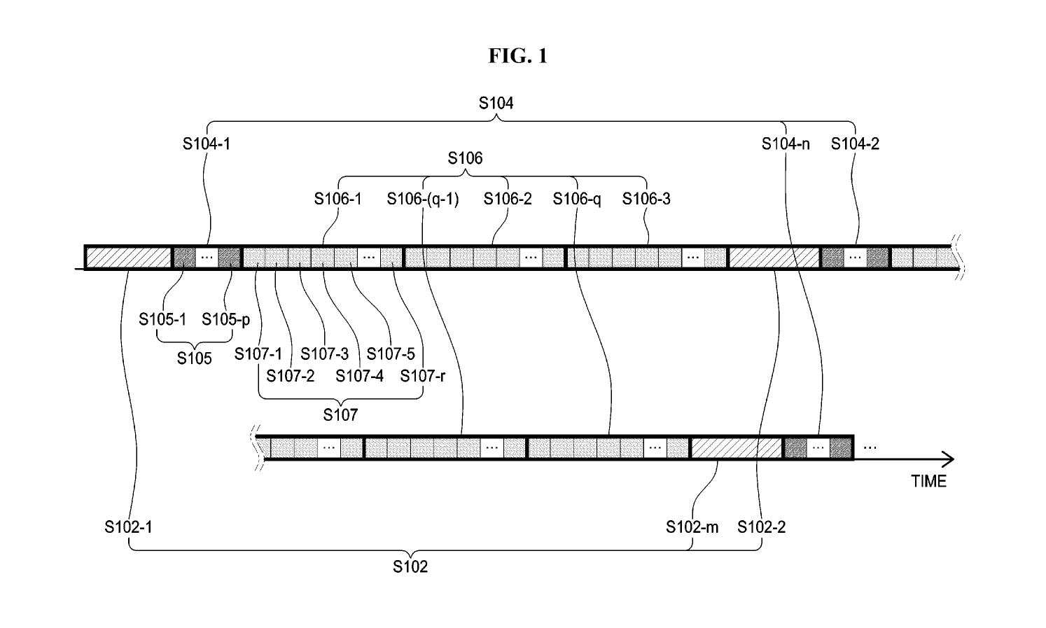

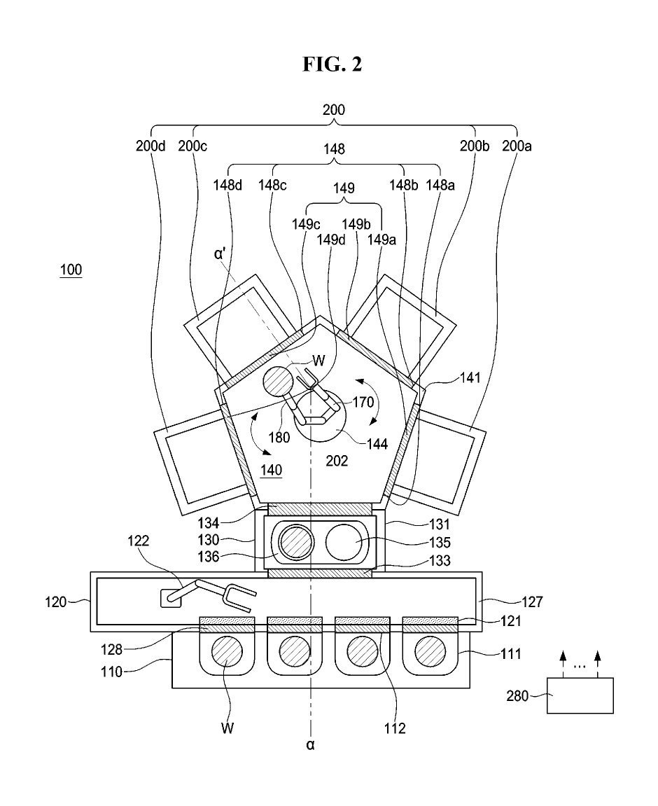

A substrate processing method according to an embodiment will be described with reference to FIG. 1. FIG. 1 is a diagram illustrating state transitions of a reactor (hereinafter also referred to as “RC”). As shown in FIG. 2, a substrate processing apparatus includes a plurality of RCs 200a, 200b, 200d and 200d (also collectively referred to as RC 200). The RC 200 is a process chamber in which the substrate is processed. The detailed configuration of the RC 200 will be described later.

An idle step S102 is when the substrate processing apparatus is idle. In the idle step S102, the substrate processing apparatus is out of operation. That is, the substrate processing apparatus is not in operation. For example, the substrate processing apparatus is not in operation immediately after the installation of the substrate processing apparatus or during the maintenance thereof. Referring to FIG. 1, a first idle step S102-1 may be a time period immediately after the installation of the substrate processing apparatus, and a second idle step S102-2 may be a maintenance period during which cleaning of a component is performed. In FIG. 1, an m^{th} idle step (where m is a natural number) is denoted as “idle step S102-m.” When the idle step S102 is completed, a warm-up step (hereinafter also referred to as WU step) S104 is performed subsequently.

The WU step S104 is also referred to as standby step. Hereinafter, “warm-up” refers to bringing the state of the RC 200 closer to a processing condition of a lot processing step S106. For example, the stabilization of a heater operation is performed in the WU step S104. In FIG. 1, an n^{th} WU step (where n is a natural number) is denoted as “WU step S104-n.”

The WU step S104 includes a sub-warm-up step (hereinafter referred to as “SWU step”) S105 including SWU S105-1 through S105-p (where p is a natural number). A sub-recipe, which is included in a recipe (hereinafter also referred to as a recipe program) used in a substrate processing step S107, for a component that is to be warmed up is executed in the SWU step S105. For example, a recipe for heater control is executed when the temperature is monitored in the SWU step S105. By performing the SWU step 105 a plurality of times, the state of the RC 200 in the first substrate processing step S107-1 wherein the first substrate of the lot processing step S106 is processed is rendered to be substantially the same as the processing condition of an r^{th} substrate processing step S107-r (where r is a natural number) wherein an r^{th} substrate is processed. Hereinafter, the substrate processing step S107-1 through substrate processing step S107-r may be collectively referred to as “substrate processing step S107.” When the SWU step S105-p is completed, the substrate processing step S107-1 is performed.

The recipe program is an executable program configured to control components of the substrate processing apparatus while processing a substrate (hereinafter referred to as “wafer W”). For example, the recipe program may include a program that controls components such as a heater, a gas supply unit and a gas exhaust unit while heating the wafer W. While the recipe program is described as being executed during the processing of the wafer W, the recipe program is not limited thereto. For example, the recipe program may be configured to control the operation of the component used in placing the wafer W. Furthermore, the recipe program may include a sub-recipe for controlling each component of the substrate processing apparatus. In the warm-up step S104, a sub-recipe related to a component that is to be warmed up may be executed, and sub-recipes related to controlling other components may be executed in the lot processing step S106. For example, in the warm-up step S104, a sub-recipe for controlling the heater may be executed. In the lot processing step S106, a sub-recipe for controlling the process gas supply system may be executed.

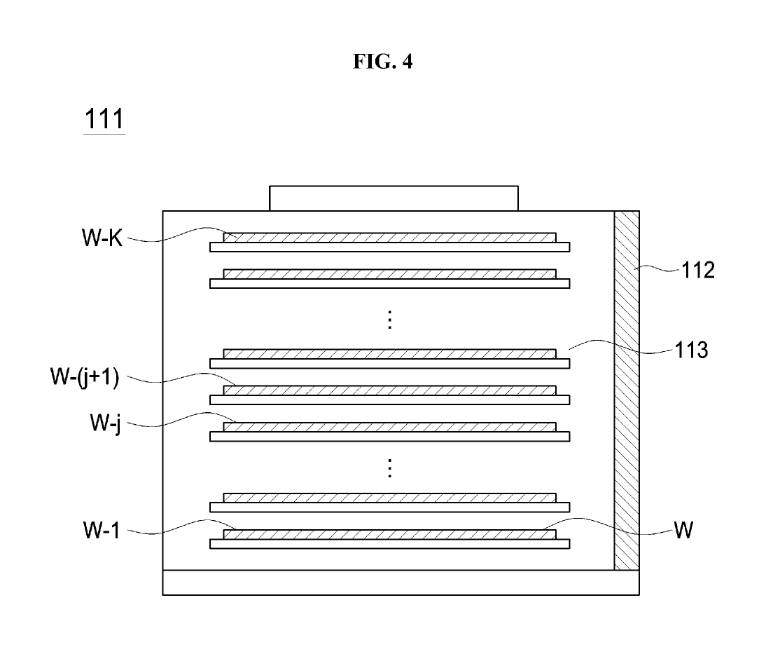

The lot processing step S106 is a step for processing one lot of wafers W loaded into the RC 200, and the substrate processing apparatus is in operation during the lot processing step S106. One lot of wafers W may include wafers W−1 through W−k (where k is a natural number) accommodated in a single pod 111 as shown in FIG. 4. In FIG. 1, the first lot processing step is denoted as “S106-1” and a q^{th} lot processing step (where q is a natural number) is denoted as “S106-q.” One wafer W is loaded into each RC 200. For example, four wafers W are brought into four RCs (e.g., 200a through 200d), respectively.

The lot processing step S106 includes substrate processing steps S107-1 through S107-r. As described later, in the substrate processing step S107, processes such as the loading/unloading (or replacement) process of the wafer W, film formation and modification are performed.

In the substrate processing step S107, when the recipe program is executed, the wafer W loaded in the RC 200 is heated by the heater. By the process gas supplied into the RC 200, the wafer W is subjected to processes such as the film-forming process and the modification process. When these processes are completed, the processed wafer W is unloaded from the RC 200, and then another wafer W to be processed next is loaded into the RC 200. Since the same substrate processing is performed in each substrate processing step S107-1 through S107-r, the same recipe program is executed.

In the substrate processing step S107, recipe program the same as that of the SWU step S105 is read and executed. By using the same recipe program in the substrate processing step S107 and the SWU step S105, the space occupied by the recipe program stored in the memory device 280c described later may be reduced. However, a dedicated recipe program for the WU step may be used. In this case, the recipe program is modified appropriately according to the substrate processing condition.

Depending on the maintenance frequency of the substrate processing apparatus, the lot processing step S106 may be performed consecutively as shown in FIG. 1. The maintenance frequency may be set according to the process to be performed. For example, the maintenance frequency is high in case of a CVD process where particles are likely to be generated, and the maintenance frequency is low in annealing processes where particles are unlikely to be generated.

### (2) Configuration of Substrate Processing Apparatus

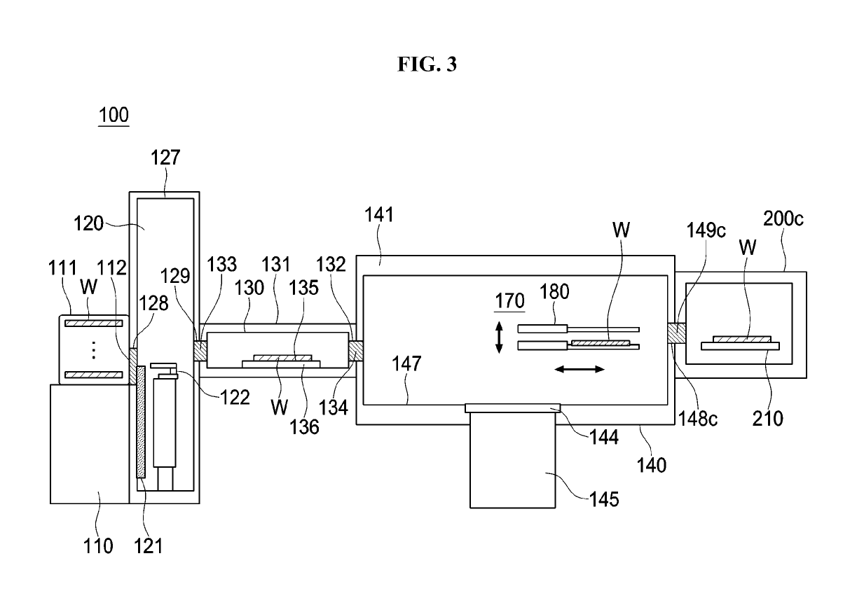

A configuration of a substrate processing apparatus according to the embodiment is described with reference to FIGS. 2 through 4. FIG. 2 schematically illustrates an exemplary horizontal cross-section of the substrate processing apparatus, FIG. 3 schematically illustrates an exemplary vertical cross-section of the substrate processing apparatus taken along the line α-α′ in FIG. 2, and FIG. 4 is a diagram illustrating a pod of the substrate processing apparatus according to the embodiment.

Referring to FIG. 2 and FIG. 3, the substrate processing apparatus 100 according to the embodiment is configured to process a wafer (substrate) W. The substrate processing apparatus 100 includes an IO stage 110, an atmospheric transfer chamber 120, a loadlock chamber 130, a vacuum transfer chamber 140 and the RC 200.

### Atmospheric Transfer Chamber and IO Stage

The IO stage 110 (loading port shelf) is provided at the front side of the substrate processing apparatus 100. A plurality of pods 111 is placed on the IO stage 110. The pod 111 is used as a carrier for transferring the wafer W such as a silicon (Si) substrate. As shown in FIG. 4, a support unit 113 configured to support the wafers W in horizontal orientation in multiple stages is provided in the pod 111.

The wafers W accommodated in the pod 111 are numbered. Specifically, as shown in FIG. 4, the wafers W are numbered, from bottom to top, as W−1, . . . , W−j, W−(j+1), . . . , W−k (where j is a natural number satisfying 1<j<k).

A cap 112 is provided at the pod 111 and is opened and closed by a pod opener 121. The pod opener 121 opens or closes the cap 112 of the pod 111 placed on the TO stage 110 such that the wafer W may be loaded into or unloaded from the pod 111. The pod 111 is loaded onto the IO stage 110 and unloaded from the IO stage 110 by AMHS (Automated Material Handling Systems) (not shown).

The TO stage 110 is provided adjacent to the atmospheric transfer chamber 120. The loadlock chamber 130, which will be described later, is connected to a side of the atmospheric transfer chamber 120 other than the side to which the IO stage 110 is provided. An atmospheric transfer robot 122 configured to transfer the wafer W is provided in the atmospheric transfer chamber 120.

A substrate loading/unloading port 128 and the pod opener 121 for transferring the wafer W into or out of the atmospheric transfer chamber 120 are provided at the front side of a housing 127 of the atmospheric transfer chamber 120. Referring to FIG. 3, a substrate loading/unloading port 129 for transferring the wafer W into or out of the loadlock chamber 130 is provided at the rear side of the housing 127 of the atmospheric transfer chamber 120. The substrate loading/unloading port 129 is opened or closed by a gate valve 133. When the substrate loading/unloading port 129 is opened, the wafer W may be loaded into the loadlock chamber 130 or unloaded from the loadlock chamber 130.

### Loadlock Chamber

The loadlock chamber 130 is provided adjacent to the atmospheric transfer chamber 120. The vacuum transfer chamber 140 which will be described later is provided at a side of the housing 131 constituting the loadlock chamber 130 other than the side of the housing 131 that is adjacent to the atmospheric transfer chamber 120.

A substrate support 136 having two placing surfaces, on which the wafer W may be placed, is provided in the loadlock chamber 130.

### Vacuum Transfer Chamber

The substrate processing apparatus 100 includes a transfer space, i.e., the vacuum transfer chamber (transfer module) 140, in which the wafer W is transported under negative pressure. A housing 141 constituting the vacuum transfer chamber 140 is pentagonal when viewed from above. The loadlock chamber 130 and the reactors (RCs) 200a, 200b, 200c and 200d where the wafer W is processed are connected to respective sides of the pentagonal housing 141. A vacuum transfer robot 170 which is a transfer robot for transferring the wafer W under negative pressure is provided at approximately the center of the vacuum transfer chamber 140 with a flange 144 as a base.

As shown in FIG. 2 and FIG. 3, the vacuum transfer robot 170 provided in the vacuum transfer chamber 140 may be lifted and lowered by an elevator 145 and the flange 144 while maintaining the vacuum transfer chamber 140 airtight. The vacuum transfer robot 170 may include two arms 180 that may be independently elevated. Only end effectors of the two arms 180 are illustrated in FIG. 3 and other components of the vacuum transfer robot 170 are omitted for simplification.

A substrate loading/unloading port 148 is provided in a sidewall of the sidewalls of the housing 141 facing each of the RCs 200a, 200b, 200c and 200d. As shown in FIG. 2, a substrate loading/unloading port 148a is provided in a sidewall of the housing 141 facing the RC 200a. Similarly, a substrate loading/unloading port 148b is provided in a sidewall of the housing 141 facing the RC 200b, a substrate loading/unloading port 148c is provided in a sidewall of the housing 141 facing the RC 200c, and a substrate loading/unloading port 148d is provided in a sidewall of the housing 141 facing the RC 200d. Hereinafter, one of the substrate loading/unloading ports 148a through 148d may be referred to as “substrate loading/unloading port 148” or all of the substrate loading/unloading ports 148a through 148d may be collectively referred to as “substrate loading/unloading port 148.” The gate valve 149 is provided to correspond to the RCs 200a, 200b, 200c and 200d. As shown in FIG. 2, the gate valve 149a is provided at the RC 200a, the gate valve 149b is provided at the RC 200b, the gate valve 149c is provided at the RC 200c, and the gate valve 149d is provided at the RC 200d. Hereinafter, one of the gate valves 149a through 149d may be referred to as gate valves 149 or all of the gate valves 149a through 149d may be collectively referred to as gate valves 149.

The arms 180 may be rotated about an axis (not shown) or extended. By rotating or extending the arms 180, the wafer W may be loaded into or unloaded from the RC 200. The arms 180 may transfer the wafer into the RC 200 in accordance with an instruction from a controller 280 indicative of the wafer numbers.

### Reactor

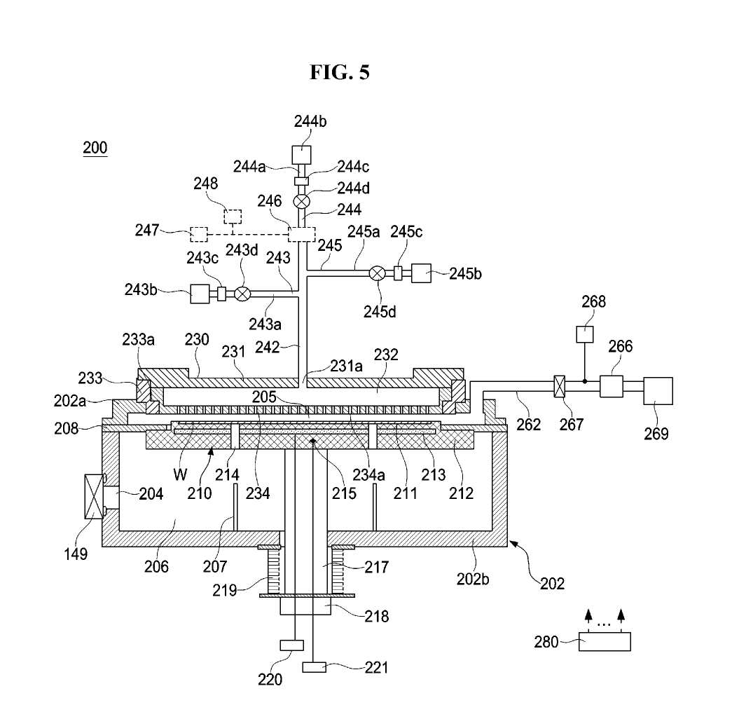

Next, the reactor (RC) 200 will be described with reference to FIG. 5. As shown in FIG. 5, the RC 200 includes, for example, a process vessel 202. The process vessel 202 includes, for example, a flat, sealed vessel having a circular horizontal cross-section. The process vessel 202 is made of a metal material such as aluminum (Al) and stainless steel (SUS). A processing space 205 where the wafer W is processed and a transfer space 206 through which the wafer W is transported into the processing space 205 are provided in the process vessel 202. The process vessel 202 includes an upper vessel 202a and a lower vessel 202b. A partition plate 208 is provided between the upper vessel 202a and the lower vessel 202b.

A substrate loading/unloading port 204 is provided on a side surface of the lower vessel 202b adjacent to the gate valve 149. The wafer W is transported between the vacuum transfer chamber 140 and the reactor 200 through the substrate loading/unloading port 204. Lift pins 207 are provided at the bottom of the lower vessel 202b.

A substrate support unit 210 is provided in the processing space 205 to support the wafer W. The substrate support unit 210 includes a substrate support 212 having a substrate placing surface 211 on which the wafer W is placed and a heater (heating unit) 213 provided in the substrate support 212. Through-holes 214 penetrated by the lift pins 207 are provided at the substrate support 212 corresponding to the locations of the lift pins 207. A heater temperature control unit 220 is connected to the heater 213. The heater temperature control unit 220 is configured to control the heater 213 based on the instructions from the controller 280 so that the heater 213 is heated to a desired temperature.

A temperature sensor 215 is provided adjacent to the heater 213. A temperature monitoring unit 221 is connected to the temperature sensor 215. The temperature monitoring unit 221 is configured to transmit the temperature detected by the temperature sensor 215 to the controller 280. The data acquired from the detected temperatures represents a state of RC 200. In the embodiment, the acquired data representing the state of the RC 200 may be also referred to process chamber data. The heater temperature control unit 220 and the temperature monitoring unit 221 are electrically connected to the controller 280. The temperature monitoring unit 221 is in operation in the WU step S104 and the lot processing step S106. According to the embodiment, the process chamber data acquired in the WU step S104 and the process chamber data acquired in the lot processing step S106 are referred to as a first process chamber data and a second process chamber data, respectively.

The substrate support 212 is supported by a shaft 217. The shaft 217 penetrates the bottom of the process vessel 202. The shaft 217 is coupled to an elevating mechanism 218 outside the process vessel 202.

The elevating mechanism 218 includes a support shaft (not shown) configured to support the shaft 217 and an actuation unit (not shown) configured to lift or rotate the support shaft. The actuation unit (not shown) may include a lift mechanism (not shown) such as a motor configured to actuate the support shaft and a rotating mechanism (not shown) such as a gear configured to rotate the support shaft.

The wafer W placed on the substrate placing surface 211 is lifted and lowered by operating the elevating unit 218 by lifting and lowering the shaft 217 and the substrate support 212. Bellows 219 covers the periphery of the lower end of the shaft 217. The interior of the processing space 205 is maintained airtight.

When the wafer W is transferred, the substrate support 212 is moved downward until the substrate placing surface 211 faces the substrate loading/unloading port 204. When the wafer W is processed, the substrate support 212 is moved upward until the wafer W reaches a processing position in the processing space 205 as shown in FIG. 5.

A shower head 230, which is a gas dispersion mechanism, is provided at an upstream side of the processing space 205. A gas introduction port 231a is provided on a cover 231 of the shower head 230. The gas introduction port 231a communicates with a common gas supply pipe 242 described later.

The shower head 230 includes a dispersion plate (dispersion mechanism) 234 for dispersing gas. A space at the upstream side of the dispersion plate 234 is referred to as a buffer space 232 and a space at the downstream side of the dispersion plate 234 is referred to as the processing space 205. The dispersion plate 234 is provided with through-holes 234a. The dispersion plate 234 is arranged to face the substrate placing surface 211. The dispersion plate 254 is, for example, disk-shaped. Through-holes 234a are provided on the entirety of the surface of the dispersion plate 234.

The upper vessel 202a includes a flange (not shown). A support block 233 is placed on and fixed to the flange (not shown). The support block 233 includes a flange 233a. The dispersion plate 234 is placed on and fixed to the flange 233a. The cover 231 is fixed to the upper surface of the support block 233.

### Supply Unit

The common gas supply pipe 242 is connected to the cover 231 to communicate with the gas introduction port 231a provided in the cover 231 of the shower head 230. A first gas supply pipe 243a, a second gas supply pipe 244a and a third gas supply pipe 245a are connected to the common gas supply pipe 242.

### First Gas Supply System

A first gas source 243b, a mass flow controller (MFC) 243c which is a flow rate controller (flow rate control unit) and a valve 243d which is an on/off valve are provided at the first gas supply pipe 243a in order from the upstream side to the downstream side of the first gas supply pipe 243a.

The first gas source 243b is the source of a first gas containing a first element. The first gas containing the first element is also referred to as a first element-containing gas. The first element-containing gas is a source gas, i.e. one of process gases. In the embodiment, the first element may include silicon (Si). That is, the first element-containing gas may include a silicon-containing gas. Specifically, gas such as dichlorosilane (Cl₂H₂Si, also referred to as DCS) gas and hexachlorodisilane (Si₂Cl₆, also referred to as HCD) gas may be used as the silicon-containing gas.

The first gas supply system 243 (also referred to as a silicon-containing gas supply system) includes the first gas supply pipe 243a, the mass flow controller 243c and the valve 243d.

### Second Gas Supply System

A second gas source 244b, a mass flow controller (MFC) 244c which is a flow rate controller (flow rate control unit) and a valve 244d which is an on/off valve are provided at the second gas supply pipe 244a in order from the upstream side to the downstream side of the second gas supply pipe 244a.

The second gas source 244b is the source of a second gas containing a second element. The second gas containing the second element is also referred to as a second element-containing gas. The second element-containing gas is one of the process gases. The second element-containing gas may act as a reactive gas.

According to the embodiment, the second element-containing gas includes the second element different from the first element. The second element-containing gas may include one of oxygen (O), nitrogen (N) and carbon (C). In the embodiment, the second element-containing gas may include a nitrogen-containing gas. Specifically, ammonia (NH₃) gas may be used as the nitrogen-containing gas.

A remote plasma unit (plasma generating unit) 246 may be provided at the second gas supply pipe 244a to process the wafer W with the second gas in plasma state. A plasma controller 247 is provided at the remote plasma unit 246. The plasma controller 247 controls the remote plasma unit 246 by applying an electric power to the remote plasma unit 246. A plasma monitoring unit 248 is provided between the remote plasma unit 246 and the plasma controller 247. The plasma monitoring unit 248 monitors the state of the remote plasma unit 246 by detecting a reflected wave from the remote plasma unit 246 when the electrical power is applied to the remote plasma unit 246. The remote plasma unit 246 is in operation in the WU step S104 and the lot processing step S106. Since the detected reflected wave affects the plasma supplied to the processing space 205, the data acquired from monitoring the reflected wave represent the state of the process chamber.

The second gas supply system 244 (also referred to as a reactive gas supply system) includes the second gas supply pipe 244a, the mass flow controller 244c and the valve 244d. The second gas supply system 244 may further include the remote plasma unit 246.

### Third Gas Supply System

A third gas source 245b, a mass flow controller (MFC) 245c which is a flow rate controller (flow rate control unit) and a valve 245d which is an on/off valve are provided at the third gas supply pipe 245a in order from the upstream side to the downstream side of the third gas supply pipe 245a.

The third gas source 245b is the source of an inert gas. For example, nitrogen (N₂) gas may be used as the inert gas.

The third gas supply system 245 includes the third gas supply pipe 245a, the mass flow controller 245c and the valve 245d.

The inert gas supplied from the third gas source 245b acts as a purge gas for purging the gas present in the process vessel 202 or in the shower head 230 in the substrate processing step (S107).

### Exhaust Unit

An exhaust unit configured to exhaust the atmosphere of the process vessel 202 will be described. An exhaust pipe 262 is connected to the process vessel 202 so as to communicate with the processing space 205. The exhaust pipe 262 is provided on the side of the processing space 205. An APC (Automatic Pressure Controller) 266, which is a pressure controller for controlling the inner pressure of the process space 205 to a predetermined pressure, is provided at the exhaust pipe 262. The APC 266 includes a valve body (not shown) capable of adjusting the degree of opening. The APC 266 adjusts the conductance of the exhaust pipe 262 in accordance with an instruction from the controller 280. A valve 267 is provided on the upstream side of the APC 266 at the exhaust pipe 262. A pressure monitoring unit 268 configured to measure the pressure of the exhaust pipe 262 is provided downstream of the valve 267.

The pressure monitoring unit 268 is configured to monitor the pressure of the exhaust pipe 262. Since the exhaust pipe 262 is spatially in communication with the processing space 205, the pressure monitoring unit 268 indirectly monitors the inner pressure of the processing space 205. The pressure monitoring unit 268 is electrically connected to the controller 280 and transmits the data of the detected pressure to the controller 280. The pressure monitoring unit 268 is in operation in the WU step S104 and the lot processing step S106. The pressure data acquired by the pressure monitoring unit 268 represents the state of the process chamber.

The exhaust pipe 262, the pressure monitoring unit 268, the valve 267 and the APC 266 are collectively referred to simply as the exhaust unit. As shown in FIG. 5, a dry pump (DP) 269 may be provided to exhaust the atmosphere of the processing space 205 through the exhaust pipe 262.

Since the atmosphere of the RC 200 is controlled by the supply unit and the exhaust unit, the supply unit and the exhaust unit are collectively referred to as an atmosphere controller in the embodiment.

### Controller

The substrate processing apparatus 100 includes the controller 280 configured to control the operation of the components of the substrate processing apparatus 100.

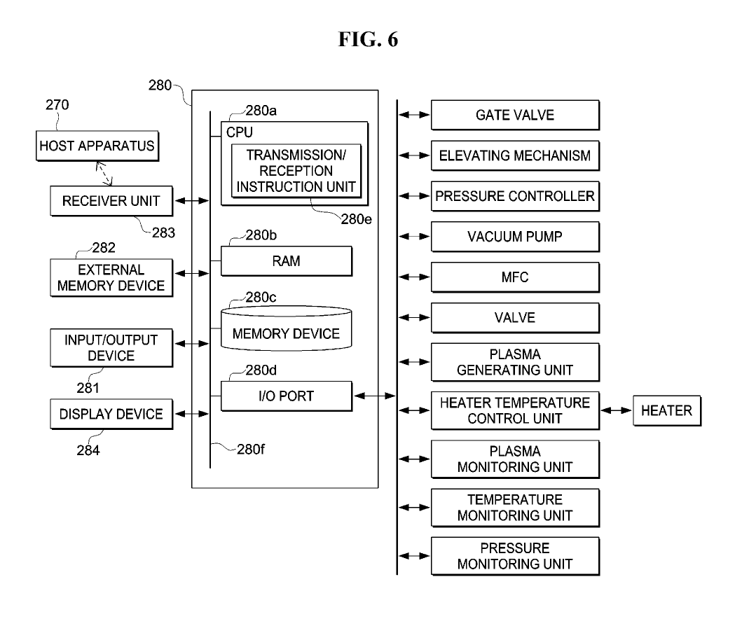

FIG. 6 schematically illustrates the configuration of the controller 280. The controller 280 which is a control unit (control means) may be embodied as a computer including a central processing unit (CPU) 280a, a random access memory (RAM) 280b, a memory device 280c as a memory unit and an I/O port 280d. The RAM 280b, the memory device 280c and the I/O port 280d can exchange data with the CPU 280a via an internal bus 280f. The data can be exchanged (transmitted or received) in the substrate processing apparatus 100 in accordance with an instruction from the transmission/reception instruction unit 280e, which is a function of the CPU 280a.

The CPU 280a can compare the data acquired by the monitoring units 221, 248 and 268 with the reference data. The CPU 280a may display the acquired data and the reference data on a display device 284. The reference data may be initial values previously recorded in the memory device 280c or values that are closest to or substantially the same as those of the pre-defined processing condition. The reference data may be obtained from another substrate processing apparatus (e.g., a second substrate processing apparatus) other than the substrate processing apparatus 100 or from another RC (e.g., a second RC) other than the RC 200. The CPU 280a compares the data acquired by the monitoring units 221, 248 and 268 with the reference data, and controls components such as heater or valves such that the acquired data is consistent with the reference data.

An input/output device 281 such as a keyboard and an external memory device 282 may be connected to the controller 280. A receiver unit 283 is electrically connected to a host apparatus 270 through a network. The receiver unit 283 may be configured to receive information from the host apparatus 270 such as processing information of the wafer W accommodated in the pod 111. The processing information of the wafer W is information related to the state of the wafer W such as a film and a pattern formed on the wafer W.

The data acquired by the monitoring units 221, 248 and 268 are displayed on the display device 284. According to the embodiment, while the display device 284 is described as a component different from the input device 281, the display device 284 is not limited thereto. For example, when the input device 281 includes a touch panel, the input device 281 and the display device 284 may be implemented as a single component.

The memory device 280c is embodied by components such as a flash memory and a hard disk drive (HDD). A process recipe having information such as sequences and conditions of the substrate processing step which will be described later, a control program for controlling the operation of the substrate processing apparatus, and tables W and L which will be described later are readably stored in the memory device 280c. The process recipe functioning as a program enables the controller 280 to execute predetermined steps of the substrate processing step to obtain a predetermined result. Hereinafter, the process recipe and control program may also be collectively referred to as “program.” Hereinafter, “program” refers to only the process recipe, only the control program, or both. The RAM 280b functions as a work area in which data such as the program and the information read by the CPU 280a are temporarily stored.

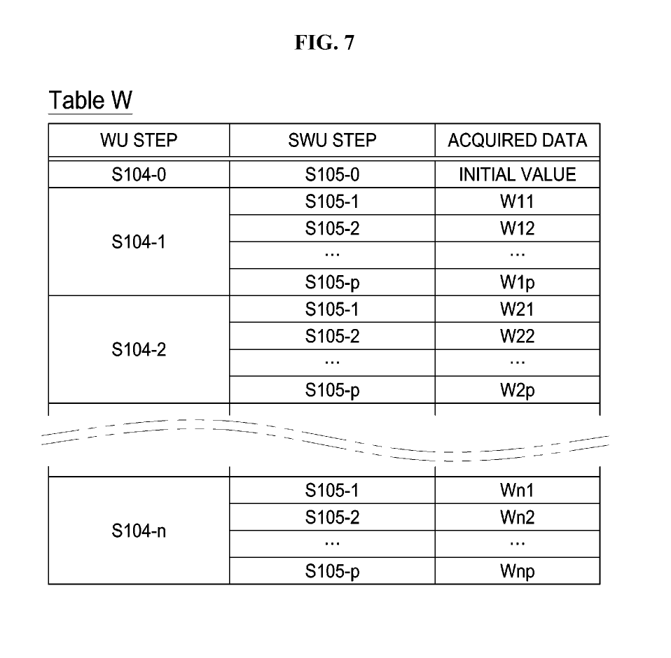

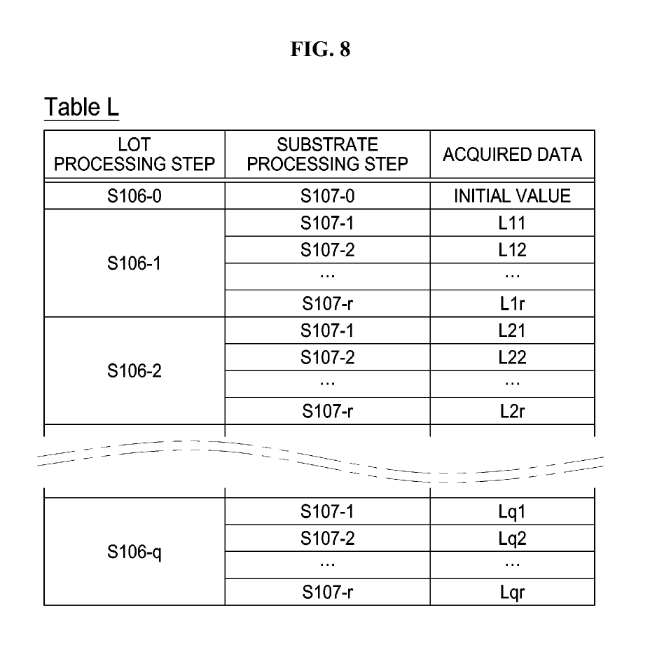

The data table W of the WU step shown in FIG. 7 and the data table L of the lot processing step shown in FIG. 8 are stored in the memory device 280c. The pre-set initial values are recorded in each of the tables W and L. The data is acquired, for example, by at least one of the plasma monitoring unit 248, the pressure monitoring unit 268 and the temperature monitoring unit 221. The acquired data is stored in real time and accumulated over time. For example, the data acquired in the SWU step S105-p of the WU step S104-n is stored in the table W as the data Wnp, and the data acquired in the substrate processing step S107-r of the lot processing step S106-q is stored in the table L as the data Lqr. The acquired data is recorded continuously in time.

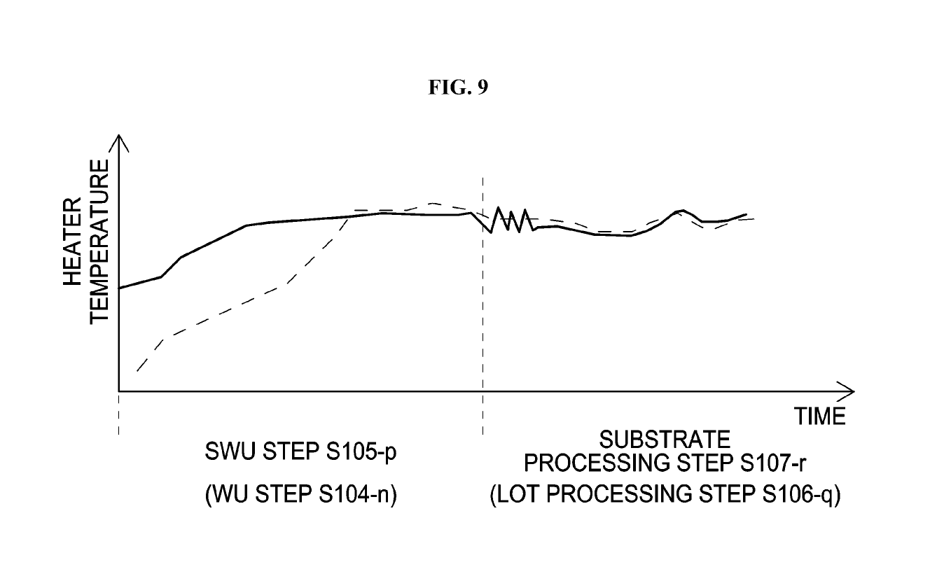

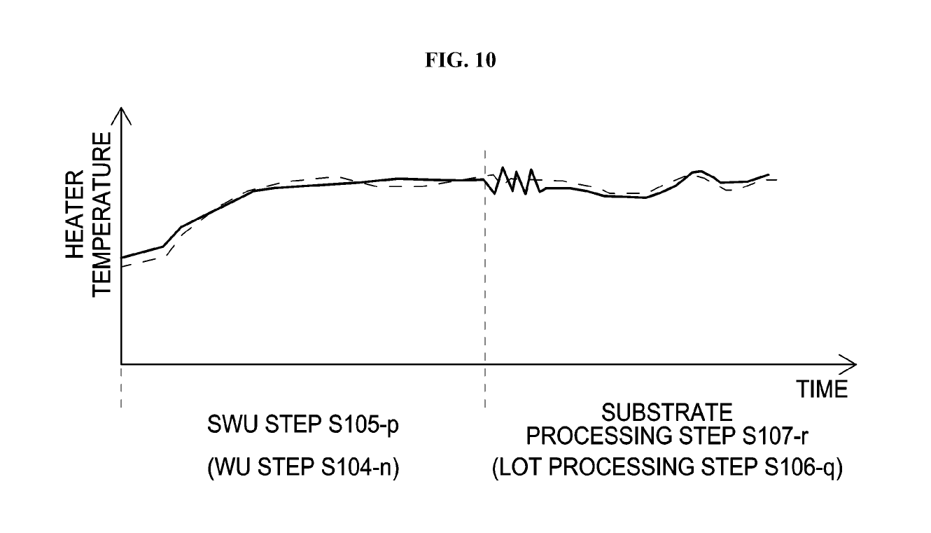

The acquired data may be displayed on the display device 284. For example, as shown in FIG. 9 and FIG. 10, the reference data (first reference data) of the WU step S104 and the reference data (second reference data) of the substrate processing step S107 may be displayed. When displaying the acquired data on the screen, the first reference data, the second reference data, the first process chamber data and the second process chamber may be displayed together for a user to review. For example, the reference data and the process chamber data may be simultaneously displayed on a single display screen. In FIG. 9, the first process chamber data and the second process chamber data acquired by the temperature monitoring unit 221 are indicated by dashed lines, and the first reference data and the second reference data are indicated by solid lines. In one embodiment, the initial value may be displayed as the reference data.

The I/O port 280d is connected to components provided in the RC 200 such as the gate valve 149, the elevating mechanism 218, the APC 266 serving as the pressure controller, the DP 269, the temperature monitoring unit 221, the plasma monitoring unit 248 and the pressure monitoring unit 268 and components of the substrate processing apparatus 100 such as the vacuum transfer robot 170.

The CPU 280a is configured to read and execute the control program stored in the memory device 280c, and read the process recipe in accordance with an instruction such as an operation command inputted from the input/output device 281. The CPU 280a may be configured to perform operations according to the process recipe such as opening and closing operations of the gate valve 149, the operation of the vacuum transfer robot 170, the elevating operations of the elevating mechanism 218, the operations of the temperature monitoring unit 221, the plasma monitoring unit 248 and the pressure monitoring unit 268, the ON/OFF operations of the DP 269, the flow rate adjusting operations of the mass flow controllers (MFCs) 243c, 244c and 245c, and the operation of the valves 243d, 244d and 245d.

The controller 280 may be embodied by installing the above-described program on a computer using the external memory device 282 storing the above-described program. The external memory device 282 may be embodied by a magnetic disk such as a hard disk, an optical disk such as a DVD, a magneto-optical disk such as MO and a semiconductor memory such as a USB memory. The method of providing the program to the computer is not limited to the external memory device 282. The program may be directly provided to the computer without using the external memory device 282 by a communication means such as the Internet and a dedicated line. The memory device 280c and the external memory device 282 are embodied by a computer-readable recording medium. Hereinafter, the memory device 280c and the external memory device 282 may be collectively referred to simply as a recording medium. In the embodiment, the term “recording medium” may refer to only the memory device 280c, only the external memory device 282, or both.

### (3) Details of Substrate Processing Method

Next, the substrate processing method will be described in detail. In the embodiment, the WU step S105 and the lot processing step S107 will be described in detail.

### WU Step S104

The WU step S104 will be described below. In the WU step S104, for example, a thermal treatment is performed such that the state of the substrate processing apparatus in the initial processing (e.g., substrate processing step S107-1) of the lot processing step S106 is as close as that of the substrate processing apparatus after a plurality of substrates are processed (e.g., the substrate processing step S107-r). That is, before the wafer W to be processed is loaded, the heater 213 is operated such that the inner temperature of the RC 200 approaches the temperature defined in the processing condition. The gas is supplied into the processing space 205 by the gas supply unit. Although the thermal treatment of the WU step S104 is exemplified, the embodiment is not limited thereto. In the WU step S104, for example, a plasma generation process or a pressure adjustment process may be performed. During the plasma generation process, the reflected wave is adjusted to approach zero in the WU step S104 as in the lot processing step 106. During the pressure adjustment process, the pressure is adjusted such that the inner pressure of the RC 200 approaches the temperature defined in the processing condition.

The process recipe is read and executed in the WU step S104, and each component of the substrate processing apparatus is controlled based on the process recipe during the thermal treatment such that the temperature of the RC 200 is substantially the same as the temperature defined in the processing condition in lot processing step S106. The recipe program may be executed multiple times to control each component such that the state of RC 200 is close to or substantially the same as the processing condition. If there is a dedicated warm-up recipe program, the dedicated warm-up recipe program is read and executed to control each component accordingly.

In the WU step S104, the temperature data is continuously acquired by the temperature sensor 215 with the heater 213 being controlled. The acquired temperature data is transmitted to the controller 280. During the plasma generation process, for example, reflected waves are continuously detected, and the data of the detected reflected wave is transmitted to the controller 280. During the pressure adjustment process, the pressure is continuously detected, and the data of the detected pressure is transmitted to the controller 280.

The acquired data is recorded in the data table W. As shown in FIGS. 9 and 10, the data recorded in the data table W is displayed as a graph on the display screen of the display device 284. Specifically, the steps associated with the recorded data, e.g. the SWU step S105-p, may be also displayed on the display screen of the display device 284 as shown in FIGS. 9 and 10.

### Lot Processing Step S106

Next, the lot processing step S106 (the substrate processing step S107) will be described. Hereinafter, an example of forming a silicon nitride (SiN) film by using HCDS gas as the first process gas and ammonia (NH₃) gas as the second process gas will be described.

After the wafer W is loaded into the process vessel 202, the gate valve 149 is closed to seal the process vessel 202. The substrate support 212 is then elevated to place the wafer W on the substrate placing surface 211 provided at the substrate support 212. By elevating the substrate support 212, the wafer W is elevated to the above-described processing position (substrate processing position).

When the wafer W is placed on the substrate support 212, power is supplied to the heater 213 embedded in the substrate support 212. The temperature of the surface of the wafer W is controlled to a predetermined temperature. The temperature of the wafer W is, for example, may range from room temperature to 800° C., preferably from room temperature to 700° C. At this time, the data acquired by the temperature sensor 215 is transmitted to the controller 280 via the heater temperature control unit 220. The controller 280 calculates a control value based on the temperature information, and instructs the heater temperature control unit 220 to control the energization state of the heater 213 based on the calculated control value to adjust the temperature of the wafer W.

With the heater 213 being controlled, the temperature sensor 215 continuously acquires the temperature data, and the acquired temperature data is transmitted to the controller 280. In order to monitor the state of the plasma generation, the plasma monitoring unit 248 continuously acquires, for example, the reflected wave, and the data of the detected reflected wave is transmitted to the controller 280. During the pressure adjustment, the pressure monitor 268 continuously acquires the pressure, and the data of the detected pressure is transmitted to the controller 280.

The acquired data is recorded in the data table L. As shown in FIGS. 9 and 10, the data recorded in the data table L is displayed as a graph on the display screen of the display device 284. Specifically, the steps associated with the recorded data, e.g. the substrate processing step S107-r, may be also displayed on the display screen of the display device 284 as shown in FIGS. 9 and 10.

While the wafer W is maintained at a predetermined temperature, the HCDS gas is supplied into the processing space 205 by the first gas supply system 243 and the NH₃ gas is supplied into the processing space 205 by the second gas supply system 244. At this time, the remote plasma unit 246 converts the NH₃ gas into a plasma state.

Thermally decomposed HCDS gas and NH₃ gas in plasma state are present in the processing space 205. By combining silicon (Si) and nitrogen (N), the silicon nitride (SiN) film is formed on the wafer W. After the SiN film having a desired thickness is formed, supply of the HCDS gas and supply of the NH₃ gas to the processing space 205 are stopped, and the HCDS gas and the NH₃ gas are exhausted from the processing space 205. When the gases are exhausted, the residual gas is purged by supplying N₂ gas by the third gas supply system 245.

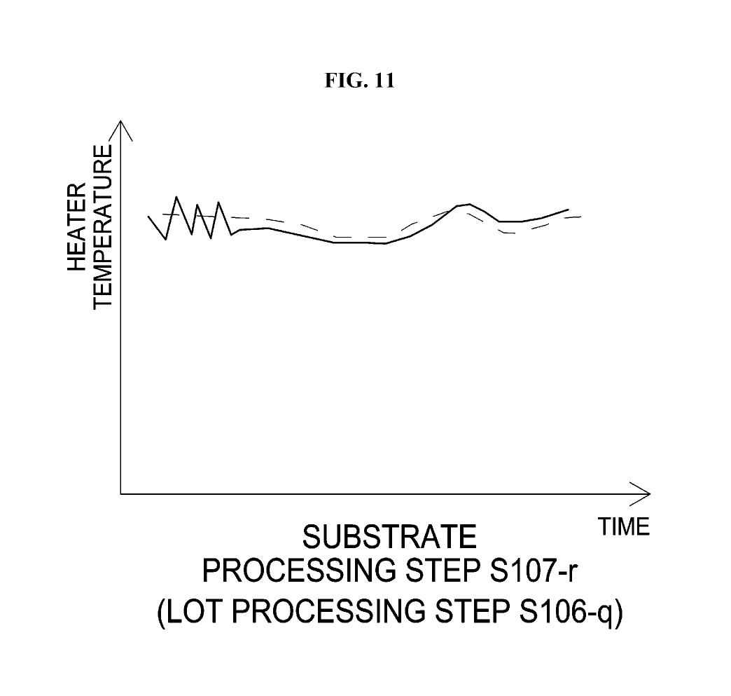

Next, the reason for acquiring the data at the lot processing step S106 and the WU step S104 will be described. First, a comparative example shown in FIG. 11 will be described. The comparative example illustrates a case that the data is acquired only in the substrate processing step S107. As illustrated in the comparative example shown FIG. 11, the temperature is measured by the temperature sensor 215 in the substrate processing step S107-r. In FIG. 11, solid line represents the reference data and dotted line represents the data generated by the temperature sensor 215.

As shown in FIG. 11, there is a discrepancy between the reference data and the acquired data. Therefore, it may be assumed that there is a problem in the heater 213. The problem may be a hardware failure such as a disconnection or an insufficient heating in the warm-up step. To determine the cause of the discrepancy, a considerable amount of work is required such as stopping the operation of the substrate processing apparatus, separating and disassembling the substrate support 212 or the shaft 217, and collecting and analyzing the disassembled components, resulting in significant degradation of productivity

The degradation of the productivity may be suppressed by determining and solving the problem without stopping the operation of the substrate processing apparatus. In order to achieve this, the data is also acquired in the WU step S104 according to the embodiment.

The data acquired in the lot processing step S106 and the WU step S104 are shown in FIG. 9 and FIG. 10. Similar to FIG. 11, solid lines in FIG. 9 and FIG. 10 represent the reference data and dashed lines represent the data acquired by the temperature monitoring unit 221.

Referring to FIG. 9, the discrepancies between the reference data and the acquired data are present in both the SWU step S105 and the substrate processing step S107. Therefore, it may be assumed that a problem occurs at least in the WU step S104. The problem may be caused by insufficient heating or excessive heating in the WU step S104. The problem may be also caused by an error in the pre-set values in the warm-up recipe program for the WU step S104 (e.g. insufficient temperature elevation due to incorrect pre-set values in ramping rate or pressure) or by excessively long idle state of the substrate processing apparatus. As described above, according to the embodiment, since determining the problem in the WU step is facilitated, the search range of the problem is narrowed as compared with the comparative example. Therefore, the user does not have to spend a lot of time to determine the problem and may quickly formulate countermeasures. The countermeasure may be an increase or decrease in the duration of the SWU step S105 and a dedicated warm up recipe.

As shown in FIG. 10, there is almost no discrepancy between the reference data and the acquired data in the SWU step S105, and there is a discrepancy in the substrate processing step S107. Therefore, it may be assumed that problem does not occur in the WU step S105 and a problem occurs in the substrate processing step S107. The cause of the problem may be the component that is not in operation in the WU step S104 or in a recipe not used in the WU step S104 and effects thereof. For example, when only an inert gas is supplied without a process gas in the WU step S104, the first gas supply unit 243 and the second gas supply unit 244 which are not used in the WU step S104 may affect the problem. The recipe program that controls the first gas supply unit 243 and the second gas supply unit 244 may affect the problem. The cause of problem may be a failure in a component monitored in the lot processing step S106. As described above, since determination of the problem in lot processing step S106 is facilitated, the search range of the problem is narrowed as compared with the comparative example. Therefore, the user does not have to spend a lot of time to determine the problem and may quickly formulate countermeasures. The countermeasure may be re-configuration of the recipe program or the sub-recipe associated with the problematic component, reset of the variables and parameters, and checking the component

By acquiring and displaying the data in both the lot processing step S106 and the WU step S104, the determination of the problem may be facilitated.

The reference data will be described hereinafter. While the reference data are described to be initial values, the reference data is not limited thereto. For example, the reference data may include the data acquired when the quality of the substrate processing is at its highest, the data from another RC (second RC) and the data from another substrate processing apparatus (second substrate processing apparatus).

When the reference data is the data acquired when the quality of the substrate processing performed in the substrate processing step S107 is at its highest, the discrepancy between the reference data and the acquired data is indicative of degradation in the quality of substrate processing. In this case, each component of the substrate processing apparatus is controlled such that the acquired data approaches the reference data to maintain the quality of substrate processing and high yield.

When the reference data includes the data from the second RC other than the RC 200 or the data from the second substrate processing apparatus other than the substrate processing apparatus 100 the discrepancy between the reference data and the acquired data is indicative of a discrepancy between the substrate processings performed in the second RC and the RC 200 or between the substrate processings performed in the second substrate processing apparatus and the substrate processing apparatus 100. In this case, each component of the substrate processing apparatus is controlled such that the acquired data approaches the reference data to maintain the quality of substrate processing and high yield.

The data may be displayed as follows. The data from the SWU step S105 may be continuously displayed from the step S105-1 through the step S105-p. By continuously displaying the data, checking of an occurrence of a problem in the SWU step is facilitated.

According to the technique described herein, the determination of the state of the process chamber is facilitated.

1. A method of manufacturing a semiconductor device, comprising:
(a) acquiring and recording a first process chamber data by detecting a state of a process chamber without a substrate loaded in the process chamber while controlling a heating unit provided in the process chamber and an atmosphere controller configured to control an atmosphere of the process chamber, wherein the first process chamber data represents the state of the process chamber including at least one of a temperature of the process chamber, a pressure of the process chamber, and a state of plasma generation;
(b) acquiring and recording a second process chamber data by detecting the state of the process chamber with the substrate loaded in the process chamber while controlling the heating unit and the atmosphere controller to process the substrate; and
(c) displaying the first process chamber data along with a first reference data on a display screen while performing (b) and displaying the second process chamber data along with a second reference data on the display screen while performing (b);
(d) determining that a substrate processing problem exists in (b) in response to identifying a discrepancy between the second process chamber data and the second reference data;
(e) determining that the substrate processing problem in (b) relates to a component or process used at least in (a) in response to a discrepancy between the first process chamber data and the first reference data; and
(f) determining that the substrate processing problem in (b) relates to a component or process not used in (a) in response to the absence of a discrepancy between the first process chamber data and the first reference data.

2. The method of claim 1, wherein the first process chamber data and the second process chamber data are consecutively acquired in (a) and (b), respectively.

3. (canceled)

4. The method of claim 1, further comprising: (g) idling the process chamber, wherein (a) is performed between (g) and (b).

5. The method of claim 4, wherein the first reference data includes a data acquired from a warm-up step different from (a) and the second reference data includes a data acquired from a substrate processing step different from (b).

6. The method of claim 5, wherein the first reference data represents a state of the process chamber closest to that of the process chamber defined in a recipe for (a), and the second reference data represents a state of the process chamber closest to that of the process chamber defined in a recipe for (b).

7. The method of claim 4, wherein the first reference data and the second reference data are stored in memory device in advance of (a) and (b).

8. The method of claim 4, wherein the first reference data includes a data representing a state of a second process chamber different from the process chamber, the first reference data being acquired while performing (a) in the second process chamber, and the second reference data includes a data representing a state of the second process chamber different from the process chamber, the second reference data being acquired while performing (b) in the second process chamber.

9. The method of claim 1, wherein the first reference data includes a data acquired from a warm-up step different from (a) and the second reference data includes a data acquired from a substrate processing step different from (b).

10. The method of claim 9, wherein the first reference data represents a state of the process chamber closest to that of the process chamber defined in a recipe for (a), and the second reference data represents a state of the process chamber closest to that of the process chamber defined in a recipe for (b).

11. The method of claim 1, wherein the first reference data and the second reference data are stored in memory device in advance.

12. The method of claim 1, wherein the first reference data includes a data representing a state of a second process chamber different from the process chamber, the first reference data being acquired while performing (a) in the second process chamber, and the second reference data includes a data representing a state of the second process chamber different from the process chamber, the second reference data being acquired while performing (b) in the second process chamber.

13. The method of claim 2, wherein the first reference data includes a data acquired from a warm-up step different from (a) and the second reference data includes a data acquired from a substrate processing step different from (b).

14. The method of claim 13, wherein the first reference data represents a state of the process chamber closest to that of the process chamber defined in a recipe for (a), and the second reference data represents a state of the process chamber closest to that of the process chamber defined in a recipe for (b).

15. The method of claim 2, wherein the first reference data and the second reference data are stored in memory device in advance.

16. The method of claim 2, wherein the first reference data includes a data representing a state of a second process chamber different from the process chamber, the first reference data being acquired while performing (a) in the second process chamber, and the second reference data includes a data representing a state of the second process chamber different from the process chamber, the second reference data being acquired while performing (b) in the second process chamber.

17-20. (canceled)
